(19) United States
(12) Patent Application Publication
(10) Pub. No.: US 2015/0032397 A1
(43) Pub. Date: Jan. 29, 2015

(54) METHOD FOR ESTIMATING DYNAMIC POWER TRANSMISSION LINE CAPACITY BY USING SYNCHRONIZED PHASOR TECHNOLOGY

(71) Applicant: GUANGDONG EAST POWER CO., LTD., Dongguan, Guangdong (CN)

(72) Inventors: Ruikun Mai, Dongguan (CN); Ling Fu, Dongguan (CN); Haibo Xu, Dongguan (CN); Simo He, Dongguan (CN)

(21) Appl. No.: 14/378,353

(22) PCT Filed: Sep. 27, 2012
(86) PCT No.: PCT/CN2012/082214

§ 371 Date: Aug. 13, 2014

(30) Foreign Application Priority Data
Feb. 14, 2012 (CN) 201210032464.1

(51) Int. Cl. G01R 27/26; G01R 25/00; G01R 21/00

(52) U.S. Cl. CPC G01R 27/2605; G01R 21/00; G01R 25/00
USPC 702/65

(57) ABSTRACT

The present invention relates to the field of electrical power systems and automation technologies thereof, and disclosed is a method for estimating a dynamic power transmission line capacity by using a synchronized phasor technology. Synchronized phasor measurement units are arranged at two sides of a power transmission line. The synchronized phasor measurement units measure voltage and current phasors of the power transmission line and transmit the voltage and current phasors to a data buffer of a measurement system for calculation. In the method for estimating a dynamic power transmission line capacity by using a synchronized phasor technology in the present invention, through a power transmission line model of mechanical characteristics, thermodynamic characteristics, and power characteristics, the length of the power transmission line is calculated by using values of synchronized voltage and current phasors at the two sides of the power transmission line, and a resistivity of the power transmission line is obtained according to a total resistance of the power transmission line, so as to obtain an estimated value of a real-time temperature of the power transmission line, thereby achieving the objective of determining the on-line power transmission capacity of the power transmission line without adding any additional device.

### FIELD OF THE INVENTION

The invention relates to the field of electrical power systems and automation technologies thereof, in particular to a method for estimating a dynamic power transmission line capacity by using a synchronized phasor technology.

### BACKGROUND OF THE INVENTION

New construction of power transmission lines is increasingly difficult due to the scarcity of land resources and high construction cost. The worst external environment is taken as a reference to consider power transmission capacity in a static method basically. Therefore, a larger margin is kept on estimation of transmission line capacity based on the static method so as to guarantee safety of power transmission lines. In the case of on-peak power utilization and relatively ideal weather, the transmission line capacity is not subject to a full utilization due to restriction of estimation of the transmission line capacity, consequently power grid is forced to switch into other power transmission corridors, thereby problems such as increasing line loss etc are possibly caused, or measures such as temporary interruption of power supply to a fraction of users are adopted, which is to the disadvantage of society development and users' demands on power grid.

Over the past ten years, relatively lots of researches are made by many scholars and researchers on estimation of the dynamic transmission line capacity, which is roughly classified into: 1. estimation of the dynamic transmission line capacity based on weather measurement, which is possibly the simplest and the most direct method as no equipment need installing on the power transmission line, heat increase per unit length of the power transmission line resulted by electric current is calculated on the basis of electric current actually flowing through the power transmission line, and heat loss of the power transmission line is obtained on the basis of current state of weather (such as wind, environment temperature and radiation etc.), in this way, net heat of the power transmission line can be calculated, thus obtaining an estimated temperature value of the power transmission line; 2. estimation of the dynamic transmission line capacity based on conductor sag and conductor tension, in this method, conductor temperature is estimated on the basis of the principle of a heated conductor being prolonged, a conductor rises in temperature and then prolongs when the transmission current becomes greater, thus increasing conductor sag, which causes tension increase of the conductor, the conductor temperature can be retrospectively calculated on the basis of the conductor sag and tension; 3. direct temperature measurement technique of the power transmission line, the most direct method, in which a temperature sensor is directly contacted with the conductor surface to measure the surface temperature of the conductor, with all factors influencing the transmission line capacity taken into account.

The first method has certain difficulty in accurate measurement of wind speed and other rapidly changing factors. In addition, it is problematic in terms of data exchange between weather stations and data centers as well as daily maintenance of weather stations due to a long transmission distance of the power transmission line; in the second method, a measuring equipment need installing on the power transmission line, the electromagnetic environment of the measuring equipment is relatively harsh, and it is extremely difficult for electromagnetic protection, communication and maintenance of the measuring equipment; in addition to the disadvantages in previously-mentioned two methods, in the third method, it is a great challenge for accurate measurement of temperature inside the conductor; furthermore, extra measuring equipment are required in the three methods and possibly need placing along the power transmission lines which possibly traverse relatively deserted zones in which communication is unavailable sometimes; high cost is required for maintenance of equipment in case of malfunction, dedicated lines are unlikely used in consideration of cost problem, thereby data communication reliability and rapidity are greatly reduced, and data transmission rate is difficult to be guaranteed.

With the continuous development of the wide-area measurement technology, a growing number of synchronized phasor measurement units are arranged in transmission grid so as to provide accurate voltage and current phasor information; accurate phasor estimation offered by the synchronized phasor technology provides a strong guarantee for estimation of dynamic transmission line capacity.

### SUMMARY OF THE INVENTION

The invention, in allusion to the disadvantages of the above-mentioned background art, provides a method for estimating a dynamic power transmission line capacity by using a synchronized phasor technology, and a power transmission line model based on mechanical characteristics, thermodynamic characteristics and power characteristics, for determining the on-line power transmission capacity of the power transmission line and also solving the disadvantage that extra measuring equipment is added.

In order to achieve above-mentioned objectives, the invention discloses a method for estimating a dynamic power transmission line capacity by using a synchronized phasor technology comprising steps as below:

(1) Synchronized phasor measurement units are arranged at two sides of a power transmission line, one side of the power transmission line is a receiving end and the opposite side of the power transmission line is a sending end; the synchronized phasor measurement units measure voltage and current phasors of the power transmission line and transmit the voltage and current phasors to a data buffer of a measurement system;

(2) The power transmission line voltage and current phasors data in the data buffer of the measurement system is used for calculation of the total impedance of the power transmission line Z(T_{C})=Z_{C}(T_{C})·γ(T_{C})·l(T_{C}),

in which,

$${Z}_{C} ( {T}_{C} ) = \sqrt{\frac{{U}_{S}^{2} - {U}_{R}^{2}}{{I}_{S}^{2} - {I}_{R}^{2}}} , γ ( {T}_{C} ) \cdot l ( {T}_{C} ) = ln ( \frac{{U}_{S} + {Z}_{C} ( {T}_{C} ) {I}_{S}}{{U}_{R} - {Z}_{C} ( {T}_{C} ) {I}_{R}} ) ,$$

Z_{C}(T_{C}) is a positive sequence impedance, γ(T_{C}) is the propagation constant of the power transmission line, l(T_{C}) is the length of the power transmission line at a temperature of T_{C}, U_{R} and I_{R} are respectively voltage phasor and Current phasor of the receiving end of the power transmission line, and U_{S} and I_{S} are respectively voltage phasor and current phasor of the sending end of the power transmission line;

(3) both the resistance R(T_{C}) and the inductance L(T_{C}) of the power transmission line are obtained on the basis of the total impedance Z(T_{C}) of the power transmission line:

$$R ( {T}_{C} ) = Re [ Z ( {T}_{C} ) ] , L ( {T}_{C} ) = \frac{Im [ Z ( {T}_{C} ) ]}{{ω}_{0}}$$

in which, ω₀ is the angular frequency of an AC signal;

(4) Both the inductance per unit length Lᵤ and the elongation coefficient ε(T_{C}) of the power transmission line are obtained on the basis of the length l(T_{C}) the inductance L(T_{C}) of the power transmission line at a temperature of T_{C}:

$${L}_{u} = \frac{L ( {T}_{C} )}{l ( {T}_{C} )} , ɛ ( {T}_{C} ) = \frac{L ( {T}_{C} )}{{L}_{u} \cdot l ( {T}_{REF} )} - 1$$

in which, l(T_{REF}) is the length of the power transmission line at a reference temperature of T_{REF};

(5) Both the resistivity ρ(T_{C}) and the real-time temperature T_{C} of the power transmission line are obtained on the basis of the elongation coefficient ε(T_{C}) and the resistance per unit length of the power transmission line:

$$ρ ( {T}_{C} ) = \frac{R ( {T}_{C} ) \cdot A ( {T}_{REF} )}{{[ 1 + ɛ ( {T}_{C} ) ]}^{2} l ( {T}_{REF} )}$$

in which, A(T_{REF}) is the cross sectional area of the power transmission line at the reference temperature of T_{REF}, the real-time temperature T_{C} of the power transmission line is obtained by referring to the power transmission line resistivity-temperature chart;

(6) A heat loss per unit length q_{src}(T_{C}) of the power transmission line is estimated on the basis of the real-time temperature T_{C} and the temperature change rate of the power transmission line:

$$\begin{matrix}{q}_{src} ( {T}_{C} ) = \frac{1}{l ( {T}_{C} )} Re ( {U}_{S} {I}_{S}^{*} - {U}_{R} {I}_{R}^{*} ) - {mC}_{p} \cdot \frac{d {T}_{C}}{d t} \\ = {a}_{0} + {a}_{1} \cdot {T}_{C}\end{matrix}$$

in which, mCₚ is the total thermal capacity per unit length of the power transmission line, a₀ and a₁ are undetermined coefficients of a fitted curve q_{src}(T_{C})=a₀+a₁·T_{C}, further the maximum permissible current estimated value

$${I}_{max} = \sqrt{\frac{( {a}_{0} + {a}_{1} \cdot {T}_{Max} )}{{R}_{u} ( {T}_{Max} )}}$$

of the power transmission line is obtained, wherein T_{Max} is the maximum permissible temperature of the i power transmission line, namely the set thermal allowance temperature;

(7) A thermal allowance out-of-limit time is obtained by carrying out an iterative operation on the basis of the maximum permissible current estimated value Iₘₐₓ the power transmission line and a heat loss model, the iterative operation has such steps as below:

A) the resistance per unit length Rₐ(T_{C}) of the power transmission line is estimated on the basis of an estimated value of the real-time temperature T_{C} of the power transmission line:

$${R}_{u} ( {T}_{C} ) = \frac{R ( {T}_{C} )}{l ( {T}_{C} )} = \frac{ρ ( {T}_{C} ) \cdot l ( {T}_{C} )}{A ( {T}_{C} ) \cdot l ( {T}_{C} )} = \frac{ρ ( {T}_{C} )}{A ( {T}_{C} )}$$

in which, A(T_{C}) is the cross sectional area of the power transmission line at the temperature of T_{C}, both ρ(T_{C}) and A(T_{C}) are obtained by referring to a real-time temperature table regarding the power transmission line;

B) the temperature change rate

$$\frac{d {T}_{C}}{d t}$$

of the power transmission line is calculated;

C) the current estimated temperature value T_{C}(t+Δt) of the power transmission line is obtained on the basis of iteration time interval Δt:

$${T}_{C} ( t + Δ t ) = {T}_{C} ( t ) + \frac{d {T}_{C}}{d t} Δ t ,$$

wherein t is the iteration time;

D) the current estimated temperature value T_{C}(t+Δt) of the power transmission line is compared with the set thermal allowance temperature T_{Max}: the current iteration time t′ is outputted as the thermal allowance out-of-limit time and the iteration is over if the current estimated temperature value T_{C}(t+Δt) of the power transmission line is more than the set thermal allowance temperature T_{Max}, wherein the current iteration time t′ is equal to the iteration time t; Step E) is switched into if the current estimated temperature value T_{C}(t+Δt) of the power transmission line is not more than the set thermal allowance temperature T_{C}(t+Δt);

E) the current iteration time t′ is outputted as the iteration time t added with the iteration time interval Δt if the current estimated temperature value T_{C}(t+Δt) of the power transmission line is not more than the set thermal allowance temperature T_{Max}; the iteration result “out-of-limit impossible” is outputted if the temperature variation is less than a set value (a set value of the measurement system), otherwise Step A) is switched into.

Further, the total impedance Z(T_{C}) of the power transmission line is calculated on the basis of a telegraph equation:

$${U}_{S} = \frac{{U}_{R} - {I}_{R} {Z}_{C} ( {T}_{C} )}{2} {e}^{γ ( {T}_{C} ) \cdot l ( {T}_{C} )} + \frac{{U}_{R} + {I}_{R} {Z}_{C} ( {T}_{C} )}{2} {e}^{- γ ( {T}_{C} ) \cdot l ( {T}_{C} )}$$

$${I}_{S} = \frac{{U}_{R} \text{/} {Z}_{C} ( {T}_{C} ) - {I}_{R}}{2} {e}^{γ ( {T}_{C} ) \cdot l ( {T}_{C} )} - \frac{{U}_{R} \text{/} {Z}_{C} ( {T}_{C} ) + {I}_{R}}{2} {e}^{- γ ( {T}_{C} ) \cdot l ( {T}_{C} )}$$

Further, the resistivity-temperature relational expression based on a fixed slope in Step (5) is as below:

$${T}_{C} = {T}_{REF} - [ \frac{ρ ( {T}_{C} )}{ρ ( {T}_{REF} )} - 1 ] \cdot {α}^{- 1}$$

in which, α is the fixed slope regarding resistivity-temperature variation, and ρ(T_{REF}) is a resistivity at the reference temperature of T_{REF}.

Further, the temperature change rate

$$\frac{d {T}_{C}}{d t}$$

is obtained on the basis of the last two estimated temperature values T_{C}(t₀) and T_{C}(t₋₁) of the power transmission line temperature T_{C} in Step (5):

$$\frac{d {T}_{C}}{d t} = \frac{{T}_{C} ( {t}_{0} ) - {T}_{C} ( {t}_{- 1} )}{{t}_{0} - {t}_{- 1}} .$$

Further, the undetermined coefficients a₀ and a₁ are obtained via a least square method:

$${a}_{1} = \frac{{T}_{C}^{T} {q}_{src} - {T}_{C}^{T} {II}^{T} {q}_{src}}{{T}_{C}^{T} {T}_{C} - {T}_{C}^{T} {II}^{T} {T}_{C}}$$

$${a}_{0} = \frac{{I}_{T} {q}_{src} {T}_{C}^{T} {T}_{C} - {T}_{C}^{T} {q}_{src} {I}^{T} {T}_{C}}{{T}_{C}^{T} {T}_{C} - {I}^{T} {T}_{C} {I}^{T} {T}_{C}}$$

in which, T_{C} is an estimated temperature matrix of the power transmission line, q_{src} is a heat loss matrix and I is a unit microscale.

Further, the temperature change rate

$$\frac{d {T}_{C}}{d t} = \frac{1}{{mC}_{p}} [ {I}^{2} \cdot {R}_{u} ( {T}_{C} ) - ( {a}_{0} + {a}_{1} {T}_{C} ) ] ,$$

in which

$$I = {I}_{max} = \sqrt{\frac{( {a}_{0} + {a}_{1} \cdot {T}_{Max} )}{{R}_{u} ( {T}_{Max} )}} .$$

In conclusion, In the method for estimating a dynamic power transmission line capacity by using a synchronized phasor technology in the invention, through a power transmission line model based on mechanical characteristics, thermodynamic characteristics and power characteristics, the length of the power transmission line is calculated by using values of synchronized voltage and current phasors at two sides of the power transmission line, and a resistivity of the power transmission line is obtained according to a total resistance of the power transmission line, so as to obtain an estimated value of a real-time temperature of the power transmission line, thereby achieving the objective of determining the on-line power transmission capacity of the power transmission line without adding any additional device.

### BRIEF DESCRIPTION OF THE DRAWINGS

FIG. 1 is a constitutional diagram of the power transmission line and the synchronized phasor measurement units in the invention.

### DETAILED DESCRIPTION OF THE PREFERRED EMBODIMENTS

Further detailed description of the invention is made in conjunction with the accompanying drawings and embodiments in order to have a more particular knowledge of characteristics, technological means, specific objectives and functions of the invention.

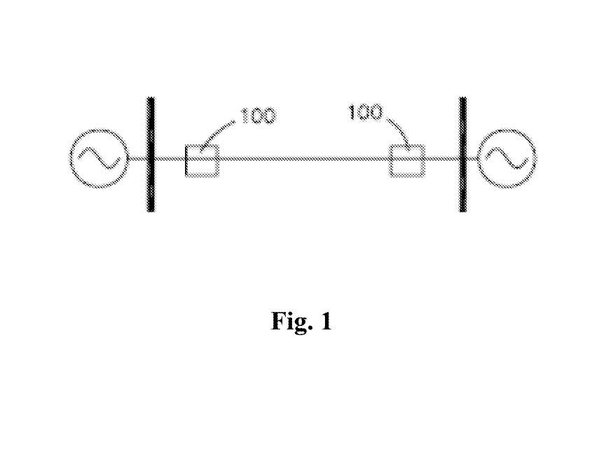

As shown in FIG. 1, a method for estimating a dynamic power transmission line capacity by using a synchronized phasor technology in the invention is realized by the steps as below:

(1) Synchronized phasor measurement units (100) are arranged at two sides of a power transmission line, one side of the power transmission line is a receiving end and the opposite side of the power transmission line is a sending end; the synchronized phasor measurement units (100) measure voltage and current phasors of the power transmission line and transmit the voltage and current phasors to a data buffer of a measurement system;

(2) The power transmission line voltage and current phasors data in the data buffer of the measurement system is used for calculation of the total impedance Z(T_{C}) of the power transmission line on the basis of a telegraph equation:

$${U}_{S} = \frac{{U}_{R} - {I}_{R} {Z}_{C} ( {T}_{C} )}{2} {e}^{γ ( {T}_{C} ) \cdot l ( {T}_{C} )} + \frac{{U}_{R} + {I}_{R} {Z}_{C} ( {T}_{C} )}{2} {e}^{- γ ( {T}_{C} ) \cdot l ( {T}_{C} )}$$

$${I}_{S} = \frac{{U}_{R} \text{/} {Z}_{C} ( {T}_{C} ) - {I}_{R}}{2} {e}^{γ ( {T}_{C} ) \cdot l ( {T}_{C} )} - \frac{{U}_{R} \text{/} {Z}_{C} ( {T}_{C} ) + {I}_{R}}{2} {e}^{- γ ( {T}_{C} ) \cdot l ( {T}_{C} )}$$

in which, Z_{C}(T_{C}) is a positive sequence impedance of the power transmission line, γ(T_{C}) is the propagation constant of the power transmission line, l(T_{C}) is the length of the power transmission line at a temperature of T_{C}, U_{R} and I_{R} are respectively voltage phasor and current phasor of the receiving end of the power transmission line, and U_{S} and I_{S} are respectively voltage phasor and current phasor of the sending end of the power transmission line;

at this moment,

$${Z}_{C} ( {T}_{C} ) = \sqrt{\frac{{U}_{S}^{2} - {U}_{R}^{2}}{{I}_{S}^{2} - {I}_{R}^{2}}} , γ ( {T}_{C} ) \cdot l ( {T}_{C} ) = ln ( \frac{{U}_{S} + {Z}_{C} ( {T}_{C} ) {I}_{S}}{{U}_{R} - {Z}_{C} ( {T}_{C} ) {I}_{R}} ) ,$$

the total impedance of the power transmission line Z(T_{C})=Z_{C}(T_{C})·γ(T_{C})·l(T_{C}).

(3) Both the resistance R(T_{C}) and the inductance L(T_{C}) of the power transmission line are obtained on the basis of the total impedance Z(T_{C}) of the power transmission line:

$$R ( {T}_{C} ) = Re [ Z ( {T}_{C} ) ] , L ( {T}_{C} ) = \frac{Im [ Z ( {T}_{C} ) ]}{{ω}_{0}}$$

in which, ω₀ is the angular frequency of an AC signal;

(4) Both the inductance per unit length Lᵤ and the elongation coefficient ε(T_{C}) of the power transmission line are obtained on the basis of the length l(T_{C}) the inductance L(T_{C}) of the power transmission line at a temperature of T_{C}:

$${L}_{u} = \frac{L ( {T}_{C} )}{l ( {T}_{C} )} , ɛ ( {T}_{C} ) = \frac{L ( {T}_{C} )}{{L}_{u} \cdot l ( {T}_{REF} )} - 1$$

in which, l(T_{REF}) is the length of the power transmission line at a reference temperature of T_{REF}.

(5) Both the resistivity ρ(T_{C}) and the real-time temperature T_{C} of the power transmission line are obtained on the basis of the elongation coefficient ε(T_{C}) and the resistance per unit length of the power transmission line:

$$ρ ( {T}_{C} ) = \frac{R ( {T}_{C} ) \cdot A ( {T}_{REF} )}{{[ 1 + ɛ ( {T}_{C} ) ]}^{2} l ( {T}_{REF} )}$$

in which, A(T_{REF}) is the cross sectional area of the power transmission line at the reference temperature of T_{REF}, the real-time temperature T_{C} of the power transmission line is obtained by referring to the power transmission line resistivity-temperature chart provided by the manufacturer, a resistivity-temperature relational expression based on a fixed slope is as below:

$${T}_{C} = {T}_{REF} - [ \frac{ρ ( {T}_{C} )}{ρ ( {T}_{REF} )} - 1 ] \cdot {α}^{- 1}$$

in the formula, α is the fixed slope regarding resistivity-temperature variation, and ρ(T_{REF}) is a resistivity at the reference temperature of T_{REF}.

(6) A heat loss per unit length q_{src}(T_{C}) of the power transmission line is estimated on the basis of the real-time temperature T_{C} and the temperature change rate of the power transmission line:

$$\begin{matrix}{q}_{src} ( {T}_{C} ) = \frac{1}{l ( {T}_{C} )} Re ( {U}_{S} {I}_{S}^{*} - {U}_{R} {I}_{R}^{*} ) - {mC}_{p} \cdot \frac{d {T}_{C}}{d t} \\ = {a}_{0} + {a}_{1} \cdot {T}_{C}\end{matrix}$$

in which, mCₚ is the total thermal capacity per unit length of the power transmission line, a₀ and a₁ are undetermined coefficients of a fitted curve q_{src}(T_{C})=a₀+a₁·T_{C}, the temperature change rate

$$\frac{d {T}_{C}}{d t}$$

(namely, the temperature derivative) is obtained on the basis of the last two estimated temperature values T_{C}(t₀) and T_{C}(t₋₁) of the power transmission line temperature T_{C} in Step (5):

$$\frac{d {T}_{C}}{d t} = \frac{{T}_{C} ( {t}_{0} ) - {T}_{C} ( {t}_{- 1} )}{{t}_{0} - {t}_{- 1}} .$$

At this moment, the undetermined coefficients a₀ and a₁ of the fitted curve q_{src}(T_{C})=a₀+a₁·T₀ are obtained via a least square method:

$${a}_{1} = \frac{{T}_{C}^{T} {q}_{src} - {T}_{C}^{T} {II}^{T} {q}_{src}}{{T}_{C}^{T} {T}_{C} - {T}_{C}^{T} {II}^{T} {T}_{C}}$$

$${a}_{0} = \frac{{I}^{T} {q}_{src} {T}_{C}^{T} {T}_{C} - {T}_{C}^{T} {q}_{src} {I}^{T} {T}_{C}}{{T}_{C}^{T} {T}_{C} - {I}^{T} {T}_{C} {I}^{T} {T}_{C}^{T}}$$

in which, T_{C} is an estimated temperature matrix of the power transmission line, q_{src} is a heat loss matrix and I is a unit microscale, further the maximum permissible current estimated value

$${I}_{max} = \sqrt{\frac{( {a}_{0} + {a}_{1} \cdot {T}_{Max} )}{{R}_{u} ( {T}_{Max} )}}$$

of the power transmission line is obtained, wherein T_{Max} is the maximum permissible temperature of the power transmission line, namely the set thermal allowance temperature.

(7) A thermal allowance out-of-limit time is obtained by carrying out an iterative operation on the basis of the maximum permissible current estimated value Iₘₐₓ of the power transmission line and a heat loss model, the iterative operation has such steps as below:

A) the resistance per unit length Rᵤ(T_{C}) of the power transmission line is estimated on the basis of an estimated value of the real-time temperature T_{C} of the power transmission line:

$${R}_{u} ( {T}_{C} ) = \frac{R ( {T}_{C} )}{l ( {T}_{C} )} = \frac{ρ ( {T}_{C} ) \cdot l ( {T}_{C} )}{A ( {T}_{C} ) \cdot l ( {T}_{C} )} = \frac{ρ ( {T}_{C} )}{A ( {T}_{C} )}$$

in which, A(T_{C}) is the cross sectional area of the power transmission line at the temperature of T_{C}, both ρ(T_{C}) and A(T_{C}) are obtained by referring to a real-time temperature table regarding the power transmission line via a formula or a form provided by the manufacturer regarding the power transmission line.

B) The temperature change rate

$$\frac{d {T}_{C}}{d t}$$

of the power transmission line is calculated:

$$\frac{d {T}_{C}}{d t} = \frac{1}{{mC}_{p}} [ {I}^{2} \cdot {R}_{u} ( {T}_{C} ) - ( {a}_{0} + {a}_{1} {T}_{C} ) ] ,$$

in which

$$I = {I}_{max} = \sqrt{\frac{( {a}_{0} + {a}_{1} \cdot {T}_{Max} )}{{R}_{u} ( {T}_{Max} )}} .$$

C) The current estimated temperature value T_{C}(t+Δt) of the power transmission line is obtained on the basis of the iteration time interval Δt:

$${T}_{C} ( t + Δ t ) = {T}_{C} ( t ) + \frac{d {T}_{C}}{d t} Δ t ,$$

wherein t is the iteration time.

D) The current estimated temperature value T_{C}(t+Δt) of the power transmission line is compared with the set thermal allowance temperature T_{Max}: the current iteration time t′ is outputted as the thermal allowance out-of-limit time and the iteration is over if the current estimated temperature value T_{C}(t+Δt) of the power transmission line is more than the set thermal allowance temperature T_{Max}, wherein the current iteration time t′ is equal to the iteration time t; Step E) is switched into if the current estimated temperature value T_{C}(t+Δt) of the power transmission line is not more than the set thermal allowance temperature T_{Max}.

E) The current iteration time t′ is outputted as the iteration time t added with the iteration time interval Δt if the current estimated temperature value T_{C}(t+Δt) of the power transmission line is not more than the set thermal allowance temperature T_{Max}; the iteration result “out-of-limit impossible” is outputted if the temperature variation is less than a set value (a set value of the measurement system), otherwise Step A) is switched into.

In conclusion, In the method for estimating a dynamic power transmission line capacity by using a synchronized phasor technology in the invention, through a power transmission line model based on mechanical characteristics, thermodynamic characteristics and power characteristics, the length of the power transmission line is calculated by using values of synchronized voltage and current phasors at two sides of the power transmission line, and a resistivity of the power transmission line is obtained according to a total resistance of the power transmission line, so as to obtain an estimated value of a real-time temperature of the power transmission line, thereby achieving the objective of determining the on-line power transmission capacity of the power transmission line without adding any additional device.

The above-mentioned embodiment is only one embodiment of the invention, which is subject to a detailed and specific description but not interpreted as restriction of scope of the invention. It is necessary to point out that, those of ordinary skill in the art can, under the precondition of not breaking away from the inventive concept, make a plurality of changes and improvements of the embodiment mentioned above, which is within the scope of protection of the invention. Therefore, the scope of protection of the invention is subject to claims enclosed.

What is claimed is:

1. A method for estimating dynamic power transmission line capacity by using synchronized phasor technology wherein comprising steps as below:
(1) Synchronized phasor measurement units (100) are arranged at two sides of a power transmission line, one side of the power transmission line is a receiving end and the opposite side of the power transmission line is a sending end; the synchronized phasor measurement units (100) measure voltage and current phasors of the power transmission line and transmit the voltage and current phasors to a data buffer of a measurement system;
(2) The power transmission line voltage and current phasors data in the data buffer of the measurement system is used for calculation of the total impedance of the power transmission line Z(T_{C})=Z_{C}(T_{C})·γ(T_{C})·l(T_{C}),
in which,
$${Z}_{C} ( {T}_{C} ) = \sqrt{\frac{{U}_{S}^{2} - {U}_{R}^{2}}{{I}_{S}^{2} - {I}_{R}^{2}}} , γ ( {T}_{C} ) \cdot l ( {T}_{C} ) = ln ( \frac{{U}_{S} + {Z}_{C} ( {T}_{C} ) {I}_{S}}{{U}_{R} - {Z}_{C} ( {T}_{C} ) {I}_{R}} ) ,$$
Z_{C}(T_{C}) is a positive sequence impedance of the power transmission line, γ(T_{C}) is the propagation constant of the power transmission line, l(T_{C}) is the length of the power transmission line at a temperature of T_{C}, U_{R} and I_{R} are respectively voltage phasor and current phasor of the receiving end of the power transmission line, and U_{S} and I_{S} are respectively voltage phasor and current phasor of the sending end of the power transmission line;
(3) both the resistance R(T_{C}) and the inductance L(T_{C}) of the power transmission line are obtained on the basis of the total impedance Z(T_{C}) of the power transmission line:
$$R ( {T}_{C} ) = Re [ Z ( {T}_{C} ) ] , L ( {T}_{C} ) = \frac{Im [ Z ( {T}_{C} ) ]}{{ω}_{0}}$$
in which, ω₀ is the angular frequency of an AC signal;
(4) Both the inductance per unit length Lᵤ and the elongation coefficient ε(T_{C}) of the power transmission line are obtained on the basis of the length l(T_{C}) the inductance L(T_{C}) of the power transmission line at a temperature of T_{C}:
$${L}_{u} = \frac{L ( {T}_{C} )}{l ( {T}_{C} )} , ɛ ( {T}_{C} ) = \frac{L ( {T}_{C} )}{{L}_{u} \cdot l ( {T}_{REF} )} - 1$$
in which, l(T_{REF}) is the length of the power transmission line at a reference temperature of T_{REF};
(5) Both the resistivity ρ(T_{C}) and the real-time temperature T_{C} of the power transmission line are obtained on the basis of the elongation coefficient ε(T_{C}) and the resistance per unit length of the power transmission line:
$$ρ ( {T}_{C} ) = \frac{R ( {T}_{C} ) \cdot A ( {T}_{REF} )}{{[ 1 + ɛ ( {T}_{C} ) ]}^{2} l ( {T}_{REF} )}$$
in which, A(T_{REF}) is the cross sectional area of the power transmission line at the reference temperature of T_{REF}, the real-time temperature T_{C} of the power transmission line is obtained by referring to the power transmission line resistivity-temperature chart;
(6) A heat loss per unit length q_{src}(T_{C}) of the power transmission line is estimated on the basis of the real-time temperature T_{C} and the temperature change rate of the power transmission line:
$$\begin{matrix}{q}_{src} ( {T}_{C} ) = \frac{1}{l ( {T}_{C} )} Re ( {U}_{S} {I}_{S}^{*} - {U}_{R} {I}_{R}^{*} ) - {mC}_{p} \cdot \frac{d {T}_{C}}{d t} \\ = {a}_{0} + {a}_{1} \cdot {T}_{C}\end{matrix}$$
in which, mCₚ is the total thermal capacity per unit length of the power transmission line, a₀ and a₁ are undetermined coefficients of a fitted curve q_{src}(T_{C})=a₀+a₁·T_{C}, further the maximum permissible current estimated value
$${I}_{max} = \sqrt{\frac{( {a}_{0} + {a}_{1} \cdot {T}_{Max} )}{{R}_{u} ( {T}_{Max} )}}$$
of the power transmission line is obtained, wherein T_{Max} is the maximum permissible temperature of the power transmission line, namely the set thermal allowance temperature;
(7) A thermal allowance out-of-limit time is obtained by carrying out an iterative operation on the basis of the maximum permissible current estimated value Iₘₐₓ of the power transmission line and a heat loss model, the iterative operation has such steps as below:
A) the resistance per unit length Rₐ(T_{C}) of the power transmission line is estimated on the basis of an estimated value of the real-time temperature T_{C} of the power transmission line:
$${R}_{u} ( {T}_{C} ) = \frac{R ( {T}_{C} )}{l ( {T}_{C} )} = \frac{ρ ( {T}_{C} ) \cdot l ( {T}_{C} )}{A ( {T}_{C} ) \cdot l ( {T}_{C} )} = \frac{ρ ( {T}_{C} )}{A ( {T}_{C} )}$$
in which, A(T_{C}) is the cross sectional area of the power transmission line at the temperature of T_{C}, both ρ(T_{C}) and A(T_{C}) are obtained by referring to a real-time temperature table regarding the power transmission line;
B) the temperature change rate
$$\frac{d {T}_{C}}{d t}$$
of the power transmission line is calculated;
C) the current estimated temperature value T_{C}(t+Δt) of the power transmission line is obtained on the basis of an iteration time interval Δt:
$${T}_{C} ( t + Δ t ) = {T}_{C} ( t ) + \frac{d {T}_{C}}{d t} Δ t ,$$
wherein t is the iteration time;
D) the current estimated temperature value T_{C}(t+Δt) of the power transmission line is compared with the set thermal allowance temperature T_{Max}: the current iteration time t′ is outputted as the thermal allowance out-of-limit time and the iteration is over if the current estimated temperature value T_{C}(t+Δt) of the power transmission line is more than the set thermal allowance temperature T_{Max}, wherein the current iteration time t′ is equal to the iteration time t; Step E) is switched into if the current estimated temperature value T_{C}(t+Δt) of the power transmission line is not more than the set thermal allowance temperature T_{Max};
E) the current iteration time t′ is outputted as the iteration time t added with the iteration time interval Δt if the current estimated temperature value T_{C}(t+Δt) of the power transmission line is not more than the set thermal allowance temperature T_{Max}; the iteration result “out-of-limit impossible” is outputted if the temperature variation is less than a set value (a set value of the measurement system); otherwise Step A) is switched into.

2. The method for estimating dynamic power transmission line capacity by using synchronized phasor technology of claim 1, wherein the total impedance Z(T_{C}) of the power transmission line is calculated on the basis of a telegraph equation:
$${U}_{S} = \frac{{U}_{R} - {I}_{R} {Z}_{C} ( {T}_{C} )}{2} {e}^{γ ( {T}_{C} ) \cdot l ( {T}_{C} )} + \frac{{U}_{R} + {I}_{R} {Z}_{C} ( {T}_{C} )}{2} {e}^{- γ ( {T}_{C} ) \cdot l ( {T}_{C} )}$$
$${I}_{S} = \frac{{U}_{R} \text{/} {Z}_{C} ( {T}_{C} ) - {I}_{R}}{2} {e}^{γ ( {T}_{C} ) \cdot l ( {T}_{C} )} - \frac{{U}_{R} \text{/} {Z}_{C} ( {T}_{C} ) + {I}_{R}}{2} {e}^{- γ ( {T}_{C} ) \cdot l ( {T}_{C} )}$$

3. The method for estimating dynamic power transmission line capacity by using synchronized phasor technology of claim 1, wherein the resistivity-temperature relational expression based on a fixed slope in Step (5) is as below:
$${T}_{C} = {T}_{REF} - [ \frac{ρ ( {T}_{C} )}{ρ ( {T}_{REF} )} - 1 ] \cdot {α}^{- 1}$$
in the formula, α is the fixed slope regarding resistivity-temperature variation, and ρ(T_{REF}) is a resistivity at the reference temperature of T_{REF}.

4. The method for estimating dynamic power transmission line capacity by using synchronized phasor technology of claim 1, wherein the temperature change rate
$$\frac{d {T}_{C}}{d t}$$
is obtained on the basis of the last two estimated temperature values T_{C}(t₀) and T_{C}(t₋₁) of the power transmission line temperature T_{C} in Step (5):
$$\frac{d {T}_{C}}{d t} = \frac{{T}_{C} ( {t}_{0} ) - {T}_{C} ( {t}_{- 1} )}{{t}_{0} - {t}_{- 1}} .$$

5. The method for estimating dynamic power transmission line capacity by using synchronized phasor technology of claim 1, wherein the undetermined coefficients a₀ and a₁ are obtained via a least square method:
$${a}_{1} = \frac{{T}_{C}^{T} {q}_{src} - {T}_{C}^{T} {II}^{T} {q}_{src}}{{T}_{C}^{T} {T}_{C} - {T}_{C}^{T} {II}^{T} {T}_{C}}$$
$${a}_{0} = \frac{{I}^{T} {q}_{src} {T}_{C}^{T} {T}_{C} - {T}_{C}^{T} {q}_{src} {I}^{T} {T}_{C}}{{T}_{C}^{T} {T}_{C} - {I}^{T} {T}_{C} {I}^{T} {T}_{C}}$$
in which, T_{C} is an estimated temperature matrix of the power transmission line, q_{src} is a heat loss matrix and I is a unit microscale.

6. The method for estimating dynamic power transmission line capacity by using synchronized phasor technology of claim 1, wherein the temperature change rate
$$\frac{d {T}_{C}}{d t} = \frac{1}{{mC}_{p}} [ {I}^{2} \cdot {R}_{u} ( {T}_{C} ) - ( {a}_{0} + {a}_{1} {T}_{C} ) ] ,$$
in which
$$I = {I}_{max} = \sqrt{\frac{( {a}_{0} + {a}_{1} \cdot {T}_{Max} )}{{R}_{u} ( {T}_{Max} )}} .$$
